(19) United States
(12) Patent Application Publication
(10) Pub. No.: US 2021/0348299 A1
(43) Pub. Date: Nov. 11, 2021

(54) COMPOSITE POLYCRYSTALLINE DIAMOND, AND COMPOSITION AND METHOD FOR MAKING THE SAME

(71) Applicant: National Taipei University of Technology, Taipei City (TW)

(72) Inventors: Yin-Tung SUN, Taipei City (TW); Po-Chuan PAN, Taipei City (TW); Wei-En CHEN, Taipei City (TW)

(21) Appl. No.: 17/039,412

(22) Filed: Sep. 30, 2020

(30) Foreign Application Priority Data
May 11, 2020 (TW) 109115534

(51) Int. Cl. C30B 29/04; B22F 3/15

(52) U.S. Cl. CPC C30B 29/04; B22F 3/15; B22F 2302/403; B22F 2304/054; B22F 2304/10; B22F 2302/406

(57) ABSTRACT

A composition for making a composite polycrystalline diamond includes a plurality of diamond particles, a plurality of boron-doped diamond particles, and an additive which is selected from the group consisting of boron oxide powder, nano-carbon material and a combination thereof. Based on the total weight of the composition, the diamond particles are present in an amount that ranges from 0.5 wt % to 99.4 wt %, the boron-doped diamond particles are present in an amount that ranges from 0.5 wt % to 99.4 wt %, and the additive is present in an amount that ranges from 0.1 wt % to 20 wt %. A method for making the composite polycrystalline diamond and a composite polycrystalline diamond made thereby are also disclosed.

### CROSS-REFERENCE TO RELATED APPLICATION

This application claims priority of Taiwanese Invention Patent Application No. 109115534, filed on May 11, 2020.

### FIELD

The disclosure relates to a diamond cutter, and more particularly to a composite polycrystalline diamond, and a composition and a method for making the same.

### BACKGROUND

Polycrystalline diamond has an extremely high hardness due to its unique crystal structure and strong covalent bonding, and thus is widely used as a wear-resistant device or a cutting tool in the industry. However, polycrystalline diamond still has a high wear rate since it is frequently used to cut objects that have a relatively high hardness and that are difficult to be processed.

In order to further increase the hardness and wear resistance of the polycrystalline diamond, a boron-doped polycrystalline diamond is usually added into the polycrystalline diamond to make a composite polycrystalline diamond cutter. During cutting operation, the composite polycrystalline diamond cutter and the object to be cut would rub against each other to produce a large amount of heat, resulting in oxidation of the boron contained in the boron-doped polycrystalline diamond so as to form boron oxide (B₂O₃) Boron oxide can increase the hardness and wear resistance of the composite polycrystalline diamond cutter, thereby extending the period of use thereof. However, the manufacturing cost of the composite polycrystalline diamond cutter would be significantly increased with an increased amount of the boron-doped polycrystalline diamond. In addition, the boron-doped polycrystalline diamond has a small amount of cobalt (Co), which would be heated and undergo a reverse catalysis reaction during the cutting operation, resulting in graphitization of the lattice structure of the boron-doped polycrystalline diamond. As such, the bonding strength of the composite polycrystalline diamond cutter would be adversely affected, which in turn reduces the hardness and wear resistance thereof. Therefore, there is still a need to develop a composite polycrystalline diamond with improved hardness, wear resistance and thermal conductivity.

### SUMMARY

Therefore, an object of the disclosure is to provide a composition and a method for making a composite polycrystalline diamond, and a composite polycrystalline diamond made thereby that can alleviate or eliminate at least one of the drawbacks of the prior art.

According to the disclosure, the composition for making the composite polycrystalline diamond includes a plurality of diamond particles, a plurality of boron-doped diamond particles and an additive which is selected from the group consisting of boron oxide powder, nano-carbon material, and a combination thereof.

Based on the total weight of the composition, the diamond particles are present in an amount that ranges from 0.5 wt % to 99.4 wt %, the boron-doped diamond particles are present in an amount that ranges from 0.5 wt % to 99.4 wt %, and the additive is present in an amount that ranges from 0.1 wt % to 20 wt %.

The method for making the composite polycrystalline diamond includes the steps of providing the aforesaid composition, and subjecting the composition to a press sintering process, so as to form the composite polycrystalline diamond.

The composite polycrystalline diamond is made by subjecting the aforesaid composition to a press sintering process, wherein the additive is sintered with the diamond particles and the boron-doped diamond particles.

### BRIEF DESCRIPTION OF THE DRAWINGS

Other features and advantages of the disclosure will become apparent in the following detailed description of the embodiments with reference to the accompanying drawings, of which:

FIG. 1 is a flow chart illustrating consecutive steps of a method for making a composite polycrystalline diamond according to the disclosure;

FIG. 2 is a schematic view illustrating the composite polycrystalline diamond according to the disclosure; and

FIG. 3 is a partially enlarged view of annotated circle A of FIG. 2 illustrating the composition of the composite polycrystalline diamond according to the disclosure.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

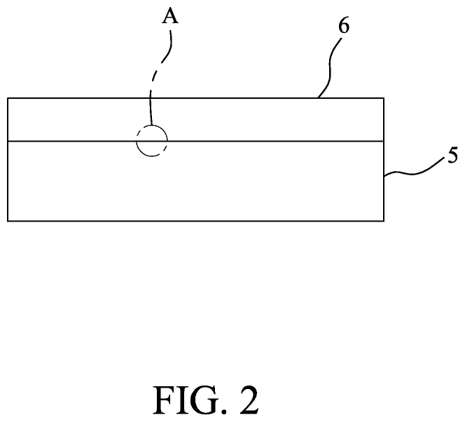

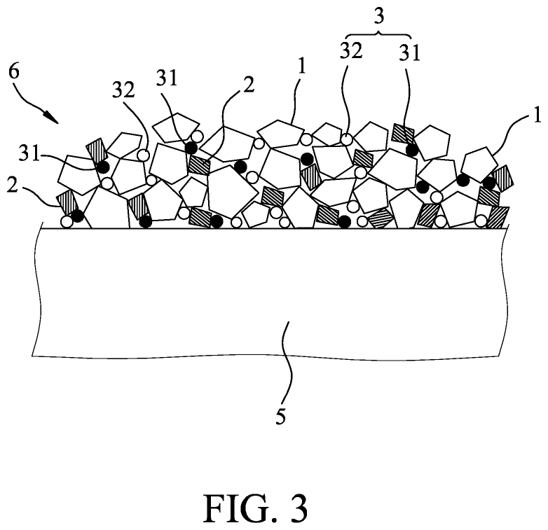

The present disclosure provides a composition for making a composite polycrystalline diamond 6 (see FIGS. 2 and 3) that includes a plurality of diamond particles 1, a plurality of boron-doped diamond particles 2, and an additive 3.

The diamond particles 1 may have an average particle size ranging from 500 nm to 50 μm. The diamond particles 1 are present in an amount that ranges from 0.5 wt % to 99.4 wt % based on the total weight of the composition.

In certain embodiments, the diamond particles 1 are present in an amount that ranges from 50 wt % to 99 wt % based on the total weight of the composition.

The boron-doped diamond particles 2 may have a trace amount of cobalt, and may have an average particle size ranging from 100 nm to 15 μm. The boron-doped diamond particles 2 are present in an amount that ranges from 0.5 wt % to 99.4 wt % based on the total weight of the composition. In certain embodiments, the boron-doped diamond particles 2 are present in an amount that ranges from 1 wt % to 50 wt % based on the total weight of the composition. Since the methods for making the diamond particles 1 and the boron-doped diamond particles 2 are well known to those skilled in the art, the detail descriptions thereof are not provided herein for the sake of brevity.

The additive 3 is selected from the group consisting of boron oxide powder 32, nano-carbon material 31, and a combination thereof. Examples of the nano-carbon material 31 suitable for used in this disclosure may include, but are not limited to, a carbon nanotube, a carbon nanocapsule, a graphene, and combinations thereof.

The additive 3 is present in an amount that ranges from 0.1 wt % to 20 wt % based on the total weight of the composition. In certain embodiments, the additive 3 may be present in an amount that ranges from 0.1 wt % to 10 wt % based on the total weight of the composition.

In certain embodiments, the composition includes the boron oxide powder 32 and the nano-carbon material 31 that are respectively present in an amount that ranges from 0.1 wt % to 10 wt % based on the total weight of the composition, and the composite polycrystalline diamond 6 made thereby has optimal frictional resistance and thermal conductivity. It should be noted that the additive 3 may be the boron oxide powder 32 only or the nano-carbon material 31 only.

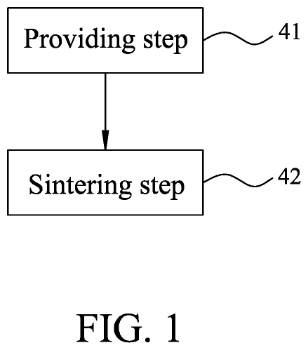

Referring to FIGS. 1 and 2, a method for making the composite polycrystalline diamond 6 includes steps S41 to S42.

In step S41, the composition as mentioned above is prepared.

In step S42, the composition is subjected to a press sintering process (e.g., a hot isostatic pressing sintering process), so as to form the composite polycrystalline diamond 6.

The press sintering process may be performed at a pressure ranging from 4 GPa to 20 GPa at a heating condition (e.g., a temperature ranging from 1200° C. to 2800° C.) for a predetermined time period (e.g., 0.5 hour to 8 hours).

In certain embodiments, during the press sintering process, the composition is disposed on rigid substrate 5 that may include carbon and tungsten (e.g., tungsten carbide).

It is noted that each of the diamond particles 1 and the boron-doped diamond particles 2 has a diamond cubic crystal structure, and thus the carbon atoms of the diamond particles 1 can interact with the carbon atoms of the boron-doped diamond particles 2 to form strong bonds (i.e., covalent bonds) during the press sintering process. Moreover, the nano-carbon material 31 and diamond are allotropes of carbon. Thus, when the composition includes the nano-carbon material 31, a portion of the nano-carbon material 31 would be covalently bonded to the diamond particles and the boron-doped diamond particles 2 in step S42, so as to enhance the thermal conductivity of the composite polycrystalline diamond 6 thus obtained.

In certain embodiments, the composition may be disposed in a die casting mold having a predetermined shape and then subjected to the press sintering process, so as to form the composite polycrystalline diamond 6 having the predetermined shape. In other embodiments, the composite polycrystalline diamond 6 maybe further subjected to a processing treatment (e.g., cutting treatment) to form a desired specific shape.

Referring to FIGS. 2 and 3, the composite polycrystalline diamond 6 is made by subjecting the aforesaid composition to the press sintering process. In the composite polycrystalline diamond 6, the additive 3 that includes the boron oxide powder 32 and the nano-carbon material 31 is sintered with the diamond particles 1 and the boron-doped diamond particles 2.

In use, the added boron oxide powder 32 is conducive for reducing the frictional resistance of the composite polycrystalline diamond 6 during cutting operation, so as to effectively enhance the wear resistant property and extend the period of use thereof. Therefore, compared with the conventional composite polycrystalline diamond that does not include the boron oxide powder 32, in order to have a comparable wear resistant property, the composite polycrystalline diamond 6 of this disclosure may have less amount of the boron-doped diamond particles 2, so as to reduce the manufacturing cost.

In addition, as compared to diamond atoms, the added nano-carbon material 31 has a larger free path of lattice vibration due to the crystal1 structure thereof, such that heat generated during the cutting operation may be effectively transferred through lattice vibration, so as to improve the thermal conductivity of the composite polycrystalline diamond 6.

Moreover, heat-induced reverse catalysis of cobalt contained in the boron-doped diamond particles 2 during the cutting operation would cause graphitization of the lattice structure of diamond atoms, and thus reduces the bond strength of the boron-doped diamond particles 2. The nano-carbon material 31 is expected to be capable of preventing the reverse catalysis of cobalt by improving thermal conductivity and maintain thermal stability of the composite polycrystalline diamond 6. In addition, the nano-carbon material 31 has a high hardness, which is also conducive for increasing the hardness of the composite polycrystalline diamond 6.

In summary, by virtue of inclusion of the boron oxide powder 32 and/or the nano-carbon material 31, the composite polycrystalline diamond 6 of this disclosure can have an enhanced wear-resistant property, hardness and thermal conductivity, thereby extending period of use and saving the manufacturing cost thereof.

In the description above, for the purposes of explanation, numerous specific details have been set forth in order to provide a thorough understanding of the embodiment. It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure . It should be further appreciated that in the description, various features are sometimes grouped together in a single embodiment, figure, or description thereof for the purpose of streamlining the disclosure and aiding in the understanding of various inventive aspects, and that one or more features or specific details from one embodiment may be practiced together with one or more features or specific details from another embodiment, where appropriate, in the practice of the disclosure.

While the disclosure has been described in connection with what are considered the exemplary embodiment, it is understood that this disclosure is not limited to the disclosed embodiment but is intended to cover various arrangements included within the spirit and scope of the broadest interpretation so as to encompass all such modifications and equivalent arrangements.

What is claimed is:

1. A composition for making a composite polycrystalline diamond, comprising:
a plurality of diamond particles;
a plurality of boron-doped diamond particles; and
an additive which is selected from the group consisting of boron oxide powder, nano-carbon material and a combination thereof,
wherein based on the total weight of the composition, said additive is present in an amount that ranges from 0.1 wt % to 20 wt %.

2. The composition of claim I wherein said diamond particles are present in an amount that ranges from 0.5 wt % to 99.4 wt % based on the total weight of the composition.

3. The composition of claim 2, wherein said diamond particles are present in an amount that ranges from 50 wt % to 99 wt % based on the total weight of the composition.

4. The composition of claim 1, wherein said boron-doped diamond particles are present in an amount that ranges from 0.5 wt % to 99.4 wt % based on the total weight of the composition.

5. The composition of claim 4, wherein said boron-doped diamond particles are present in an amount that ranges from 1 wt % to 50 wt % based on the total weight of the composition.

6. The composition of claim 1, wherein said additive is present in an amount that ranges from 0.1 wt % to 10 wt % based on the total weight of the composition.

7. The composition of claim 1, wherein said additive is said boron oxide powder.

8. The composition of claim 1, wherein said additive is said nano-carbon material, which is selected from the group consisting of carbon nanotube, carbon nanocapsule, graphene, and combinations thereof.

9. The composition of claim 1, wherein said diamond particles have an average particle size that ranges from 500 nm to 50 μm.

10. The composition of claim 1, wherein said boron-doped diamond particles have an average particle size that ranges from 100 nm to 15 μm.

11. A method for making a composite polycrystalline diamond, comprising the steps of:
providing a composition as claimed in claim 1; and
subjecting the composition to a press sintering process, so as to form the composite polycrystalline diamond.

12. The method of claim 11, wherein the press sintering process is performed at a pressure that ranges from 4 GPa to 20 GPa.

13. The method of claim 11, wherein the press sintering process is performed at a temperature that ranges from 1200° C. to 2800° C.

14. The method of claim 11, wherein the press sintering process is performed for a time period that ranges from 0.5 hour to 8 hours.

15. The method of claim 11, wherein the composition is disposed on a substrate during the press sintering process.

16. The method of claim 15, wherein the substrate includes carbon and tungsten.

17. A composite polycrystalline diamond made by subjecting a composition as claimed in claim 1 to a press sintering process, wherein an additive is sintered with diamond particles and boron-doped diamond particles.

18. The composite polycrystalline diamond of claim 17, wherein said additive is a nano-carbon material, and a portion of said nano-carbon material is covalently bonded to said diamond particles and said boron-doped diamond particles.
